(19) United States
(12) Patent Application Publication
(10) Pub. No.: US 2012/0001340 A1
(43) Pub. Date: Jan. 5, 2012

(54) METHOD AND SYSTEM FOR ALIGNMENT OF INTEGRATED CIRCUITS

(75) Inventor: Chester Frank Saj, Amsterdam, NY (US)

(73) Assignee: GENERAL ELECTRIC COMPANY, Schenectady, NY (US)

(21) Appl. No.: 12/827,440

(22) Filed: Jun. 30, 2010

(51) Int. Cl. H01L 23/538; H01L 21/50

(52) U.S. Cl. 257/773; 438/107; 257/E23.169; 257/E21.499

(57) ABSTRACT

Alignment for electronic devices using a template having holes to align the protrusions of one or more integrated circuits. There are least one integrated circuit having a plurality of protrusions arranged in a protrusion pattern. There is a template with holes disposed on the integrated circuit, wherein at least some of the holes are arranged in the protrusion pattern and the holes are disposed onto the protrusions such that a portion of the protrusions extends from the template. There is an interconnect disposed on the template, wherein the interconnect has a plurality of electric contacts, wherein at least some of the electrical contacts are arranged in the protrusion pattern, and wherein at least some of the electrical contacts are electrically coupled to at least some of the protrusions.

### BACKGROUND

Embodiments of the present disclosure relate generally to integrated circuit processing, and more particularly to alignment and packaging of integrated circuits (ICs).

It is well known that the miniaturization of electronics has paved the way for small and more compact devices. The industry continues to innovate and design higher functionality in more compact form factors thereby challenging the designers and development efforts.

As used herein, the term integrated circuits refers to the various forms of integrated circuits including Application Specific Integrated Circuits (ASIC), System on a Chip (SoC), as well as field programmable gate arrays (FPGA). Such integrated circuits are found in virtually every commercial television, portable handheld communications device, as well as medical devices.

The manufacturing and packaging of integrated circuits has reached remarkable achievements in terms of high-density devices with incredible performance. The packaging and electrical interconnection with the compact integrated circuit design has always been difficult. For example, early integrated circuits were very small, however the contacts from the integrated circuit to usable pins or leads created the bottleneck in making small devices.

The complexity of packaging increases as multiple die are configured within a single package, such as system in package (SIP) as well as multiple dies combined on a small substrate termed a multi-chip module (MCM).

In order to accommodate the high pin count of the integrated circuits, ball grid array packaging and flip-chip ball grid array packages allow for balls or bumps to connect to the entire die of the package substrate rather than the older form that used wires to couple to the edges of the die.

It may therefore be desirable to an improved alignment system and method for two or more integrated circuits. Additionally, there is a need for an alignment processing that is commercially practical and economically satisfactory.

### BRIEF DESCRIPTION

One embodiment is an alignment system for electronic devices, comprising at least one integrated circuit comprising a plurality of protrusions arranged in a protrusion pattern. There is a template with a plurality of holes disposed on the integrated circuit, wherein at least some of the holes are arranged in the protrusion pattern and the holes are disposed onto the protrusions such that a portion of the protrusions extends from the template. An interconnect is disposed on the template, the interconnect having a plurality of electric contacts, wherein at least some of the electrical contacts are arranged in the protrusion pattern, and wherein at least some of the electrical contacts are electrically coupled to at least some of the protrusions.

Another embodiment is a method for making electrical semiconductor interconnections, comprising providing one or more integrated circuits having a plurality of protrusions arranged in a protrusion pattern, disposing a template onto the integrated circuits, the template having a plurality of holes arranged in a hole pattern, wherein the hole pattern at least partially matches the protrusion pattern and at least a portion of the protrusions extend from the template. Disposing an electrical interconnect onto the template, the electrical interconnect having a plurality of electrical contacts arranged in the protrusion pattern, wherein the electrical contacts are electrically coupled to the protrusions.

A further embodiment is a device having aligned integrated circuits, including a plurality of protrusions on each of the integrated circuits, each of the integrated circuits having a protrusion pattern. There is a template with a plurality of holes with the holes arranged for each protrusion pattern, wherein the template is disposed onto the integrated circuits such that a portion of the protrusions extends from the holes of the template. An interconnect is disposed over the template, the interconnect having a plurality of electric contacts, wherein the electrical contacts are arranged according to the protrusion pattern of the integrated circuits, and wherein the electrical contacts are electrically coupled to the protrusions.

### DRAWINGS

These and other features, aspects, and advantages of the present technique will become better understood when the following detailed description is read with reference to the accompanying drawings in which like characters represent like parts throughout the drawings, wherein:

FIG. 1 is a side view of an integrated circuit device showing applicable features;

FIG. 2 is a top view of several integrated circuits showing the alignment and spacing therebetween;

FIG. 3 is a side view perspective of a template for the alignment of protrusions, in accordance with aspects of the present system;

FIG. 4a is a top view perspective of different integrated circuit designs;

FIG. 4b is a top view perspective of the corresponding templates for the different integrated circuits of FIG. 4a, according to an embodiment of the present system;

FIG. 5 is a flow chart illustrating an exemplary method for integrated circuit alignment, in accordance with aspects of the present technique;

FIG. 6a is a top view exploded perspective of template showing the holes and the protrusion, in accordance with aspects of the present system;

FIG. 6b is a side view perspective of the integrated circuit showing the protrusions and template, in accordance with aspects of the present system;

FIG. 7a is a side view perspective of two stacked integrated circuits with respective templates, in accordance with aspects of the present system;

FIG. 7b is a side view perspective of two stacked integrated circuits with a single template, in accordance with aspects of the present system; and

FIG. 7c is a side view perspective of two stacked integrated circuits including an interconnect, in accordance with aspects of the present system.

### DETAILED DESCRIPTION

The following description presents systems and methods for alignment of integrated circuits. Particularly, certain embodiments illustrated herein describe systems and methods for aligning one or more integrated circuits or chips for electrical connectivity such as to a flex circuit. The present system in one aspect describes a template having holes corresponding to the bumps or balls of the integrated circuits and is disposed onto the bumps allowing a portion of the bump to protrude, and wherein the electrical or flex interconnect is electrically coupled to the portion of the bump protruding from the template.

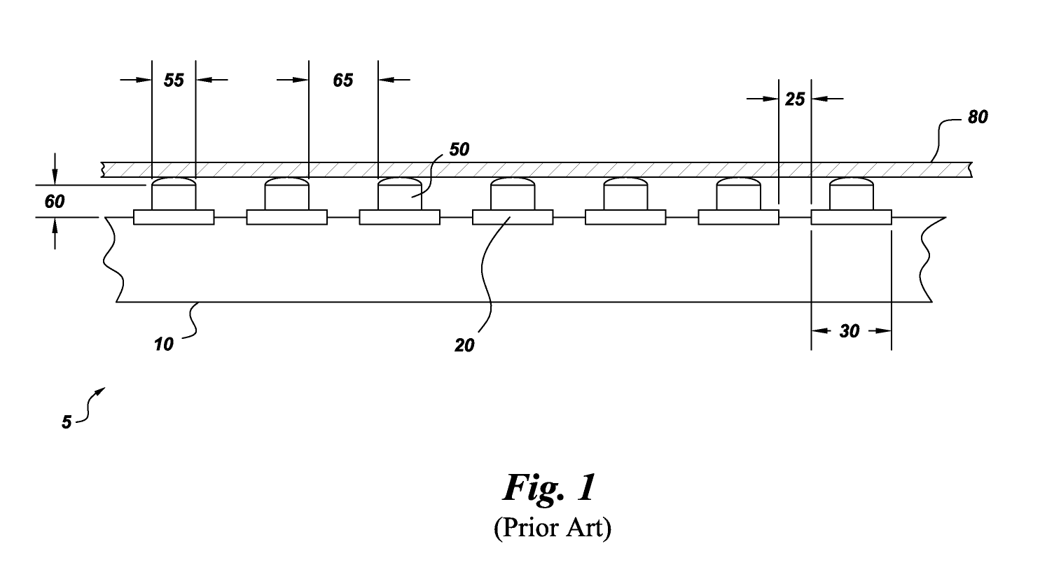

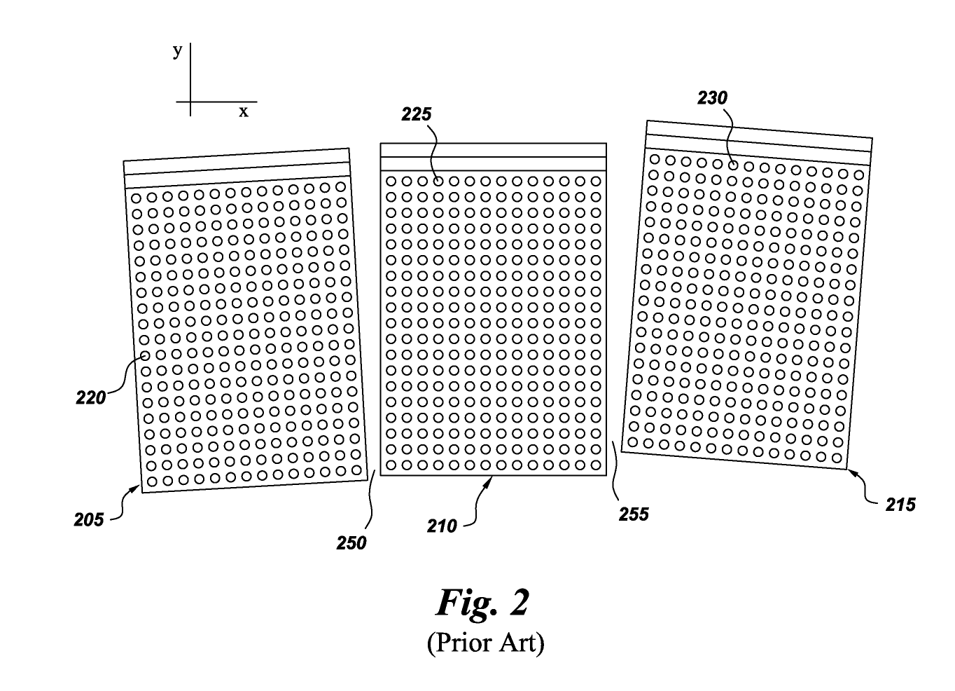

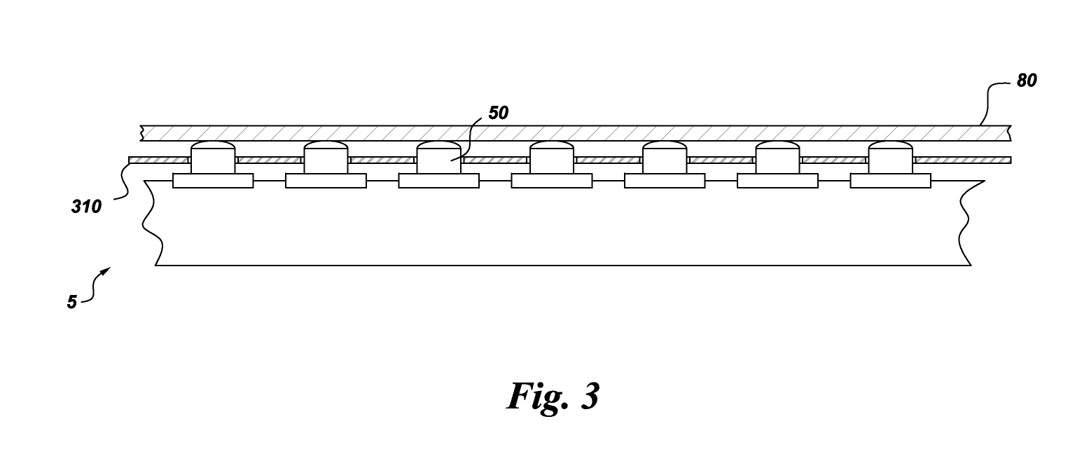

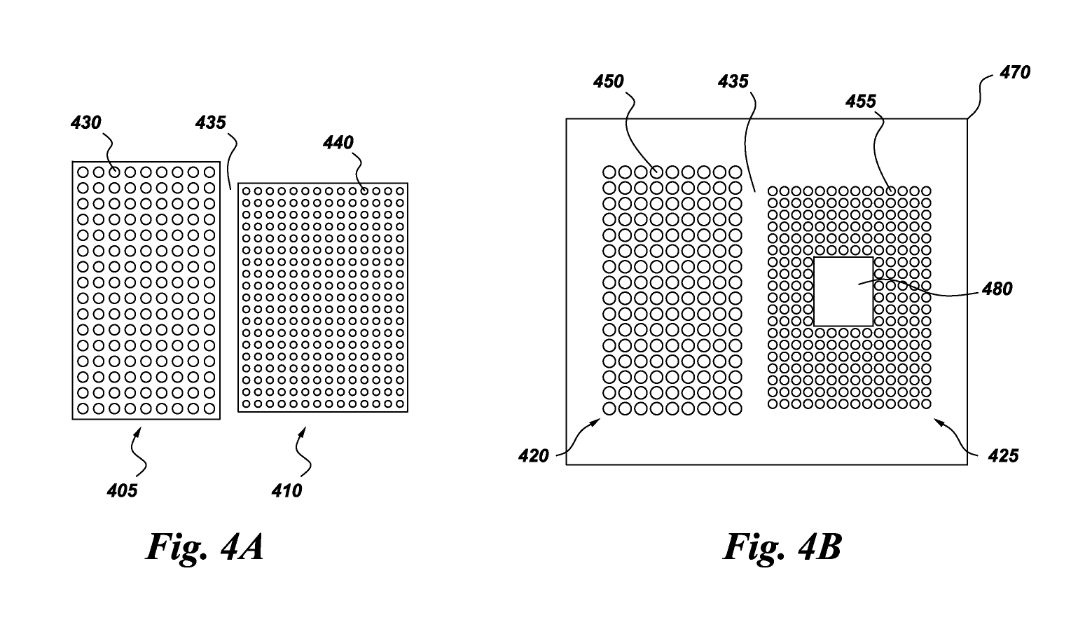

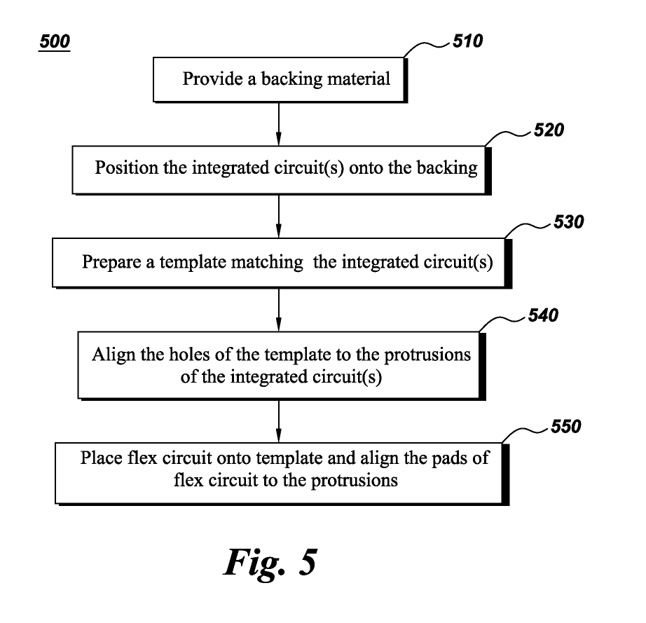

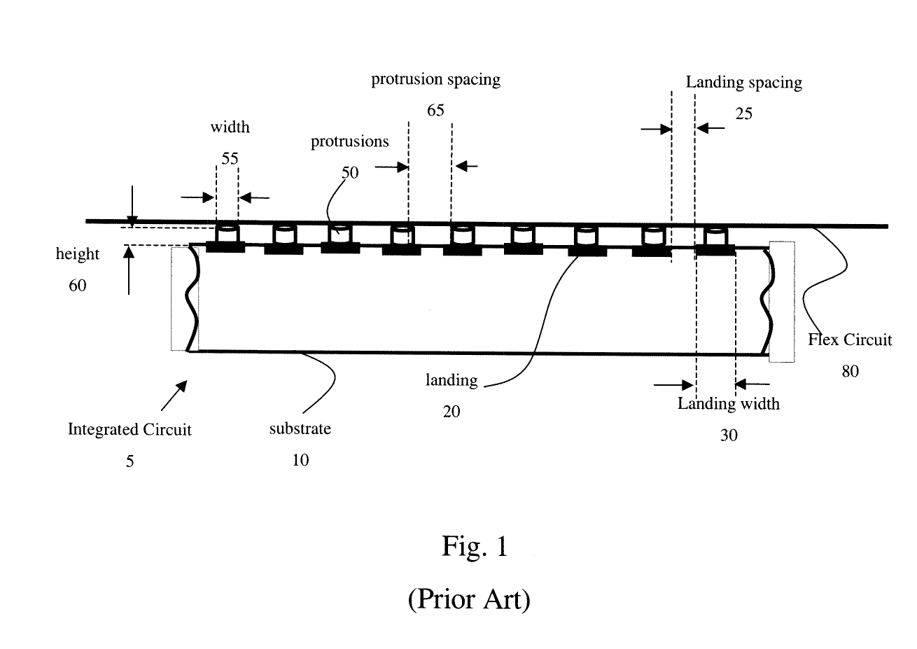

FIG. 1 illustrates a side view of a conventional integrated circuit 5. There is a substrate 10 which is typically a multiple layer semiconductor device having various electrical interconnects and layers establishing the integrated circuit 5. For convenience, the substrate 10 is illustrated as a single section. There are landings or pads 20 that are electrical contact points that are electrically coupled to the substrate 10 that can be used to establish input/output interface for the integrated circuit 5. The landings 20 can be arranged in a grid array with hundreds or thousands of landings for the integrated circuit. The dimensions of the landing 20 can vary depending upon the type of technology employed in the processing of the integrated circuit 5. The landing width 30 and the landing spacing 25 is generally related to the electrical interconnect technology and the semiconductor processing technique.

The landing 20 provide an electrical contact from the substrate 10, and there is typically a conductive protrusion 50 extending from the surface of the substrate 10. In one example, flip chip bonding uses balls, bumps, or pillars that are electrically coupled to the landings 20. The protrusions 50 have a width 55 and height 60. The protrusion spacing 65 is related to the landing spacing 25 as the protrusion 50 is coupled to the landing 20 in this example. The processing technology has continued to design smaller dimensions and more densely populated electrical connections such that the dimensions will vary depending upon the processing technology and the design criteria.

In this example, a flex circuit 80 is deployed onto the protrusions 50 with electrical pads or traces (not shown) on the flex circuit 80 in electrical contact with the protrusions 50 thereby providing routing of the various signals that make up the input/output of the integrated circuit 5. The flex circuit 80 is typically aligned to the protrusions 50 by mechanical or electro-mechanical mechanisms and can be manual, semi-automated or automated. There are various resources that facilitate the alignment process such as alignment holes or marks on the integrated circuit. The die alignment for large volume production can be accomplished by automated ‘pick and place’ equipment with visualization capability, however such equipment is expensive and generally not used for lower volume applications. However, the tight tolerances of the protrusions and the flex circuit contacts require a very precise alignment that is not easily handled by the conventional techniques.

In one particular example, the mating of the pillars or bumps of an ASIC to a flex circuit is accomplished by aligning the integrated circuit die using a text fixture with precision alignment in the X and Y direction. The flex or electrical interconnect is laid on top of the integrated circuit the conductive pads of the flex circuit are mated to the conductive pillars to form an electrical connection. This technique becomes more difficult as the size of the elements decreases along with flatness problems with the integrated circuit bumps and the flex pads. This problem is exacerbated when there is more than one integrated circuit that is combined with other integrated circuits for a device design.

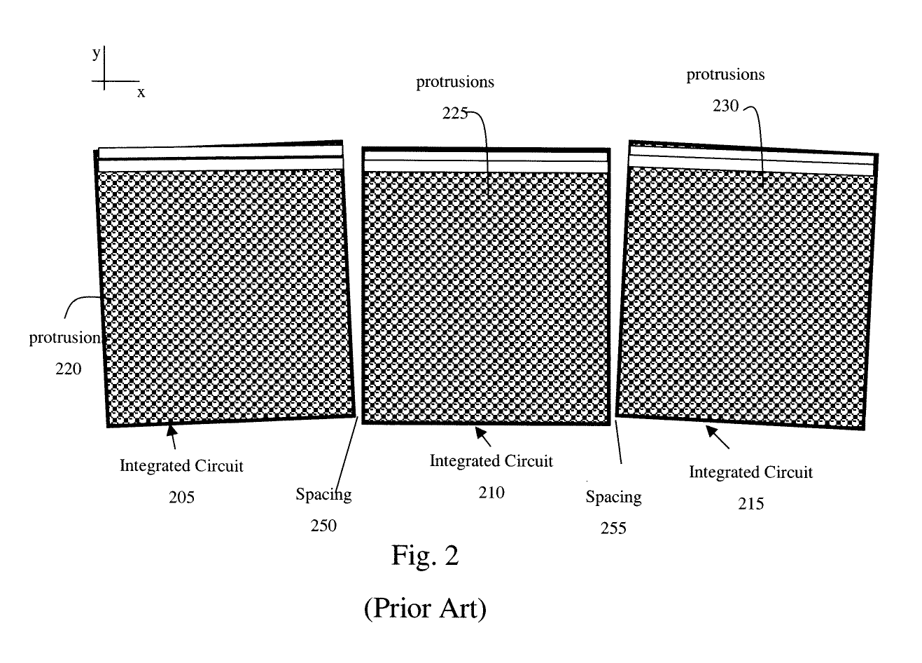

Referring to FIG. 2, an illustrative example of the alignment difficulty of multiple integrated circuits is depicted. In this example, there are three integrated circuits 205, 210, 215 that are intended to be combined into a single electronic circuit or device. There can be more or less integrated circuits and the integrated circuits.

As noted in this illustrative example, the integrated circuits 205, 210, 215 are slightly skewed such that they are not aligned according to an x and y coordinate system. Furthermore, the spacing 250, 255 between integrated circuits 205, 210, 215 is inconsistent such that the alignment of a single interconnect to these multiple integrated circuits will be difficult.

As detailed herein, the alignment of two or more separate integrated circuits tends to be very time-consuming and expensive. The integrated circuit edges have a tolerance variability such that the precision of the edges is inadequate for the flex circuit alignment. Furthermore the spacing between integrated circuits requires a further precision measurement such that the processing is labor intensive and complex.

While it is possible to cut the die such that multiple integrated circuits are integral in a single larger sized unit, there are disadvantages to having integrated multiple die. For example, if one of the integrated circuits was unsatisfactory, the entire multiple integrated circuit unit is unsatisfactory. Integrated multiple integrated circuits also restricts the system to the same integrated circuit by the same manufacturing process.

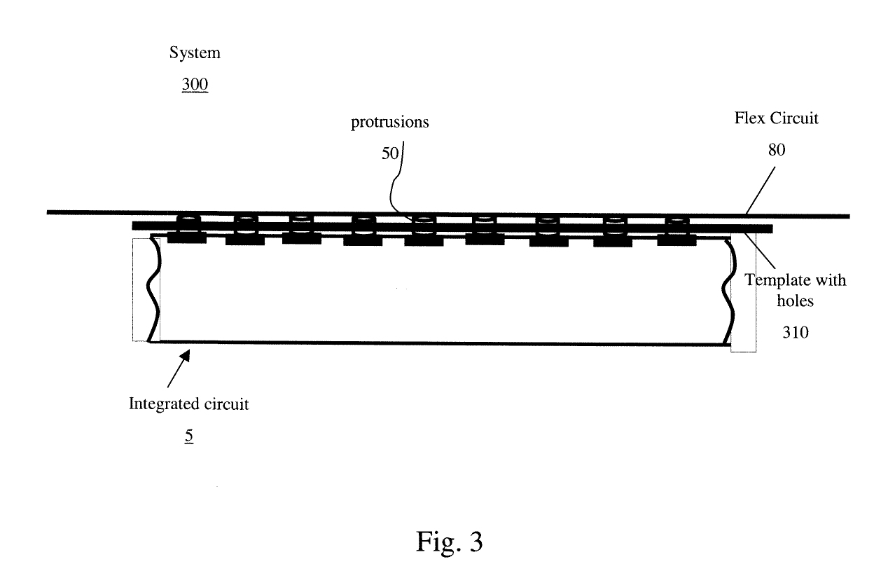

FIG. 3 depicts one embodiment of the present alignment system 300, wherein a template with holes 310 matching the protrusions 50 arrangement of the integrated circuit 5 is used to align the integrated circuit 5 and provide an easy matching with the flex circuit 80.

According to one embodiment, the template 310 is a thin film nonconductive material can be selected from a variety of nonconductive materials such as polymers glasses, ceramics, composites, or combinations thereof. One material is an organic material such as kapton, polyethylene terephthalate (PET), or another easily laser ablated polymer. The template 310 in one example is a nonconductive alignment mask of a thickness such that the tops of the bumps 20 protrude above the top of the alignment template 310 allowing for attachment of a mating surface, such as pads on the flexible circuit 80.

In one example, a non-conductive adhesive or an epoxy is disposed between the substrate and the template 310. An advantage of the present technique is the ability to use lower temperature adhesives. Flip chip processing are typically subject to solder connect at temperatures that exceed 250 degrees Celsius. For the silver epoxy die attach, temperatures are generally above 150 degrees Celsius. The alignment processing using the template allows for room temperature adhesives and processing. This permits the attachment of temperature sensitive components.

The diameter of the holes according to one example is such that the protrusions 50 protruding from the surface of the integrated circuit 5 fit into the holes in the template 310 and the protrusions 50 extend above the surface of the template 310. In one example, the template 310 is used to register the alignment of multiple individual integrated circuits to a specific pattern. Attachment to the corresponding mating surface can be accomplished using any of the known means such as solder reflow. This method also allows accurate alignment of multiple integrated circuits of different size and different pitch.

The template can employ other alignment indicia for ease of placement such as alignment holes in order to facilitate alignment to the integrated circuits. In a further example, the template may include strips or ridges on the template for aligning with the protrusions such that the template facilitates self-alignment for the holes. While this example shows a landing and a protrusion, the present disclosure defines a template for any protrusion extending from the substrate.

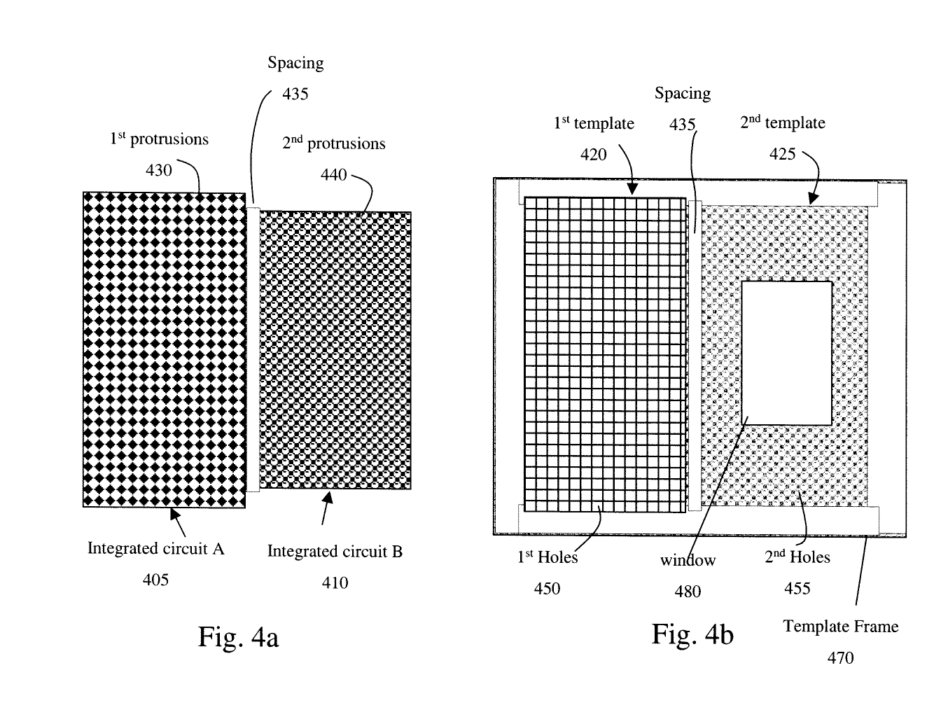

In FIG. 4a, a further example of the present system is depicted. One advantage of the template system is to accommodate varying integrated circuit size, integrated circuit shape, bump size and bump shape. According to one example, a first integrated circuit 405 has a certain shape and size that is different from a second integrated circuit 410. While the integrated circuits could employ the same bumps and bump arrangement, in this example the bump 430 of the first integrated circuit 405 differs from the bumps 440 of the second integrated circuit 410.

FIG. 4b shows the corresponding templates, wherein the first template 420 has a shape, size and hole pattern arrangement corresponding to the bump pattern on the first integrated circuit 405. Likewise, the second template 435 has a shape, size and hole pattern arrangement corresponding to the bump pattern on the second integrated circuit. This can be extended to other integrated circuits having the same or different sizes, shapes and bump/hole arrangements.

There is a window 480, illustrating a further feature of the template system, wherein the protrusion based alignment need not always require that all the holes in the template mate with the corresponding protrusions of the integrated circuits. As long as there are sufficient holes to align the integrated circuits using the protrusions as the alignment mechanism via the template, portions of the template can be open. In one example, the template covers less than the entirety of the integrated circuits such as having a window or only deployed on a region of the integrated circuits.

The template in one example is a thin film material with holes designed to align to the protrusions of the integrated circuit pattern. In one example the holes are laser drilled and measured to approximately fit over the protrusions such as solder balls, or plated or stud bumps on the integrated circuits. Using this system multiple individual integrated circuits can be quickly and accurately aligned to a single mating surface.

An advantage of the present system is that it accommodates other circuit designs and topologies. Referring to the FIG. 2 example, the protrusion pattern 220, 225, 230 on the integrated circuits 205, 210, 215 do not have to be the same and the present technique allows for different size/shape integrated circuits 405, 410 as well as protrusion arrangements 430, 440 to be combined under a single template 470 and electrical interconnect.

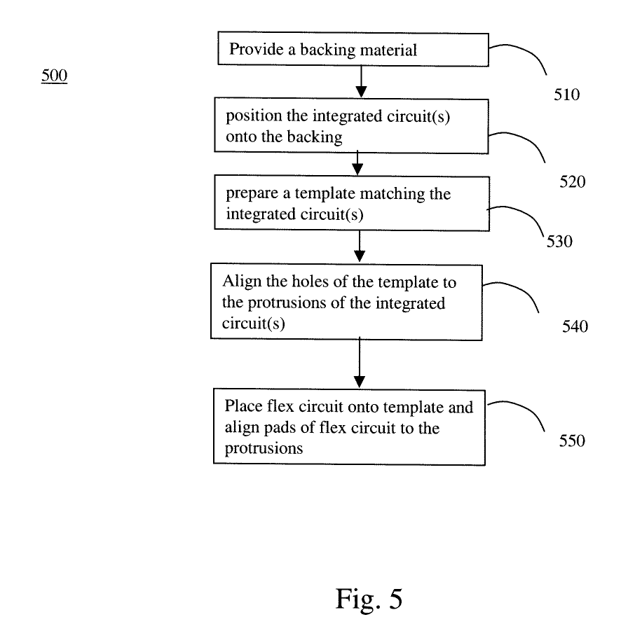

Referring to FIG. 5, a flow chart shows the alignment processing 500 according to one embodiment. In one example a backing material or other structural member is used 510, and the integrated circuits are disposed onto the backing material 520. A non-conductive adhesive or epoxy can be used to secure the backing material to the integrated circuits. In an ultrasound application, the backing material is used to absorb energy. This backing material is optional in certain applications.

A template is prepared for the integrated circuits with the template designed for the protrusions of the integrated circuits 530. The template is prepared such that the holes are perforated or drilled to match the protrusions of the integrated circuit(s) and accommodating the size/shape of the integrated circuits as well as the spacing between each integrated circuit. The template can be perforated using conventional perforation systems or made by a laser. The laser system can drill the holes or the holes can be precisely cut in any shape such as a circle, oval, square or other polygonic shape. In one example the hole pattern for the one or more integrated circuits is determined by software of the hole making system such that the hole making system receives electronic files, such as computer aided design (CAD) files indicating the protrusion arrangement either from the integrated circuit files or from the corresponding interconnect design files. As part of the drilling process, the holes may have a concave slope such that the balls or bumps tend to easily guide into the hole.

The holes of the template are aligned with the protrusions of the integrated circuits 540. It has been noted that the protrusions have a high degree of precision and reliability while the edges have a much greater variability. Thus the alignment to the protrusions improves the alignment process. In one example an alignment tool is used to place the template onto the integrated circuit and match the holes to the appropriate protrusions. Epoxy or non-conductive adhesive can be disposed between the template and the integrated circuit to secure the template. There can be alignment holes in the template that are specifically designed to aid with alignment to alignment marks on the integrated circuits. One aspect includes compressing the flex circuit to the protrusions without adhesive. For example, gold bonding of bumps to the interconnect can be accomplished without adhesive.

One embodiment of the template includes a frame extending beyond the template, wherein the template is attached to the frame and allows for improved handling of the template. The frame in one example is copper however other materials can be used. One feature of the template frame is to allow for alignment of the frame using alignment pins on the test fixture.

The flex circuit is then disposed onto the template such that the pads or traces of the interconnect are mated to the protrusions that extend through the holes 550. The interconnect provides the input/output connections for the integrated circuits.

In one example, the flex circuit is laid onto the integrated circuit alignment is aided by an alignment tool. Tooling fixtures are typically used to align the flex circuit on the integrated circuit and pressure is exerted by the tooling fixture to press out the adhesive/epoxy and compress the conductive protrusions to the appropriate conductive pads of the flex circuit by compressive displacement. In one example, compressive displacement of about 30g of pressure was applied to the protrusion and tends to slightly compress the conductive materials and form robust electrical interfaces. The amount of pressure applied to the protrusion varies depending upon several variables such as the protrusion type. For example, a softer stud bump can only require 5 g of pressure.

The interconnect in one example has copper wings integrated with a substrate base such as kapton that allows for support. One embodiment of the present system solves the problem of integrated circuit alignment of multiple chip transducers in an ultrasound probe. The interconnect wings are folded about the integrated circuits and the entire structure can be placed into a small form factor within a probe head. The integrated circuit alignment has many applications including many sensor devices.

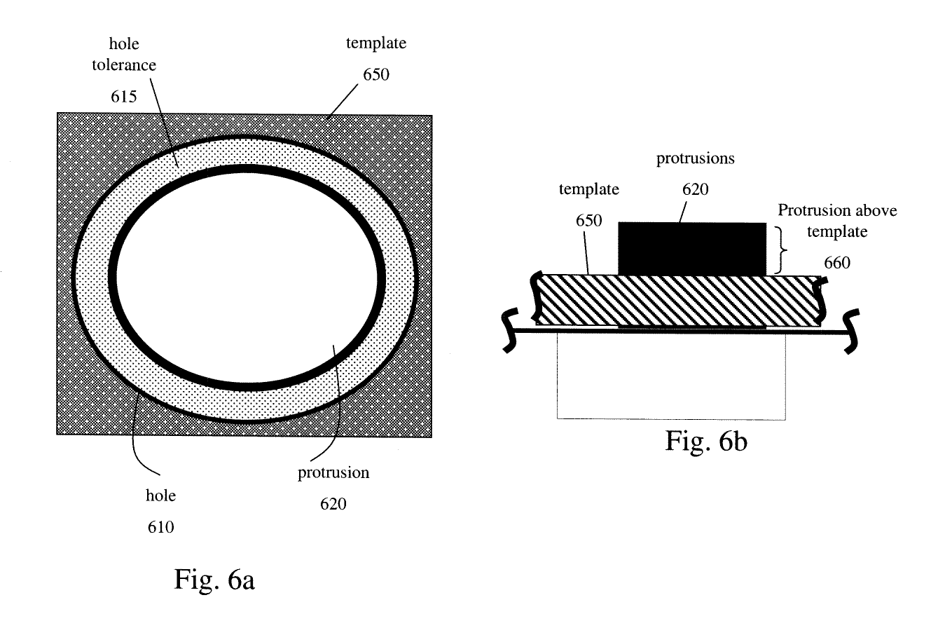

Referring to FIG. 6a, an exploded top view perspective of a protrusion 620 and template hole 610 is illustrated. The template 650 has a hole 610 with a hole tolerance 615 such that the hole 610 fits around the protrusion. This example shows a circular protrusion and a corresponding circular hole 610, however other shapes can be employed with the techniques detailed herein. As noted in FIG. 6b, an exploded side view shows the template 650 and protrusion 620. The tolerance 615 in one example is the size that allows for a suitable protrusion above the template 655 to accommodate electrical coupling to the flex circuit. In one example, the tolerance 615 extends from the size of the protrusion to a range of 5-20% of the diameter of the protrusion. As an example, if the protrusion has a 65 micron diameter, the hole tolerance can range from about 3.25 microns to 13 microns. In another example, for a rounded bump, the hole 610 may be less than the width of the rounded bump as long as there is a sufficient protrusion above the template 655. As noted, a suitable protrusion above the template 655 is a height that allows for electrical coupling to a pad of the flex interconnect (not shown) and can be in the range from about 5 microns to 50 microns. In another example, the suitable protrusion above the template is in the range from about 10 microns to 20 microns. As an example, if the protrusions are about 25 microns in height, and the template is about 12.5 microns, then the protrusion above the template 655 is about 10-12 microns and possibly less with an epoxy or adhesive disposed between the template and the substrate.

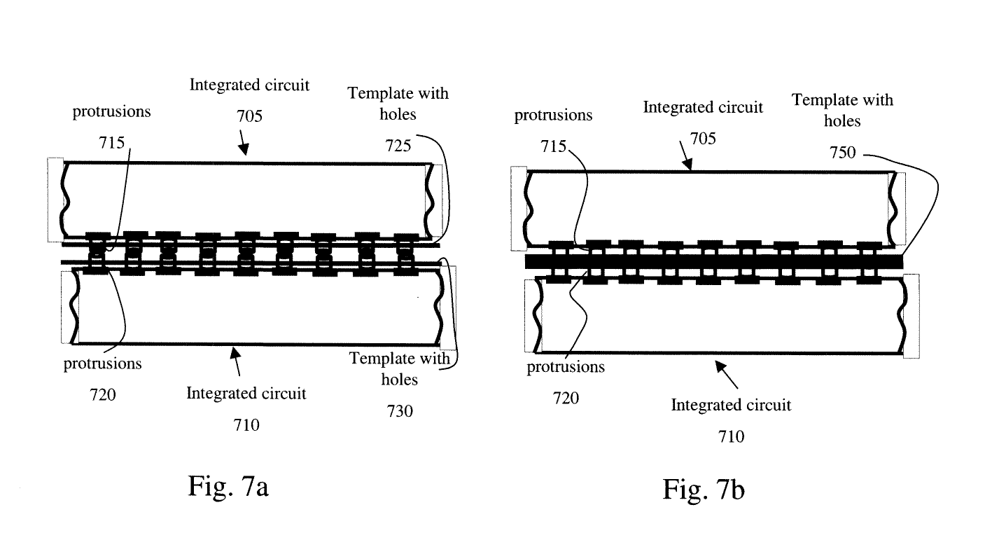

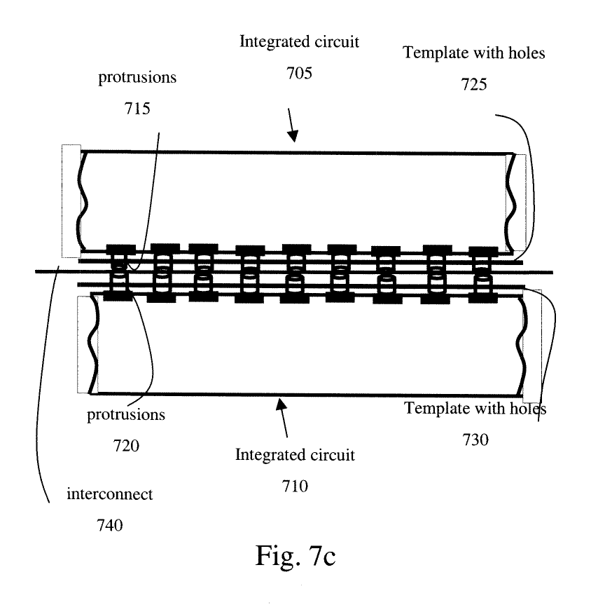

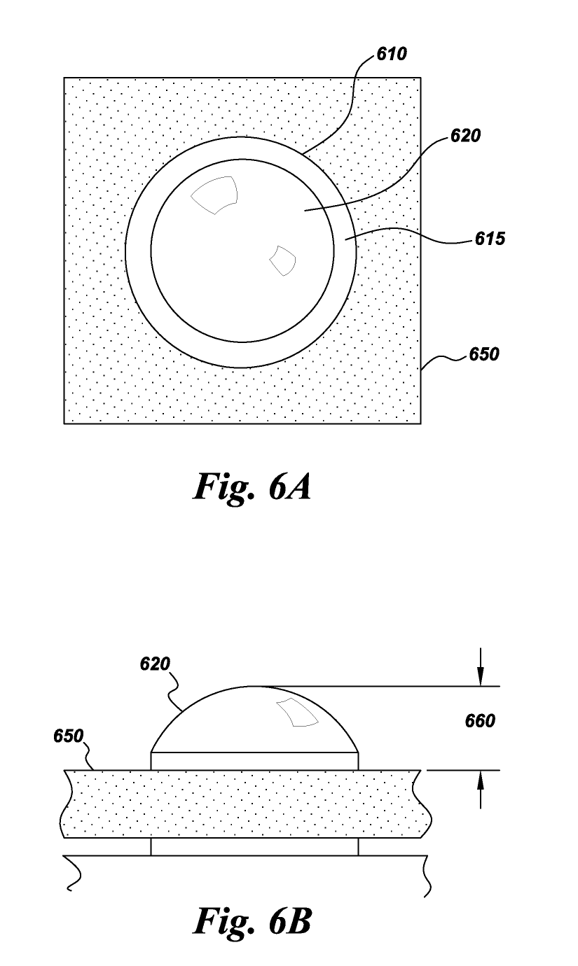

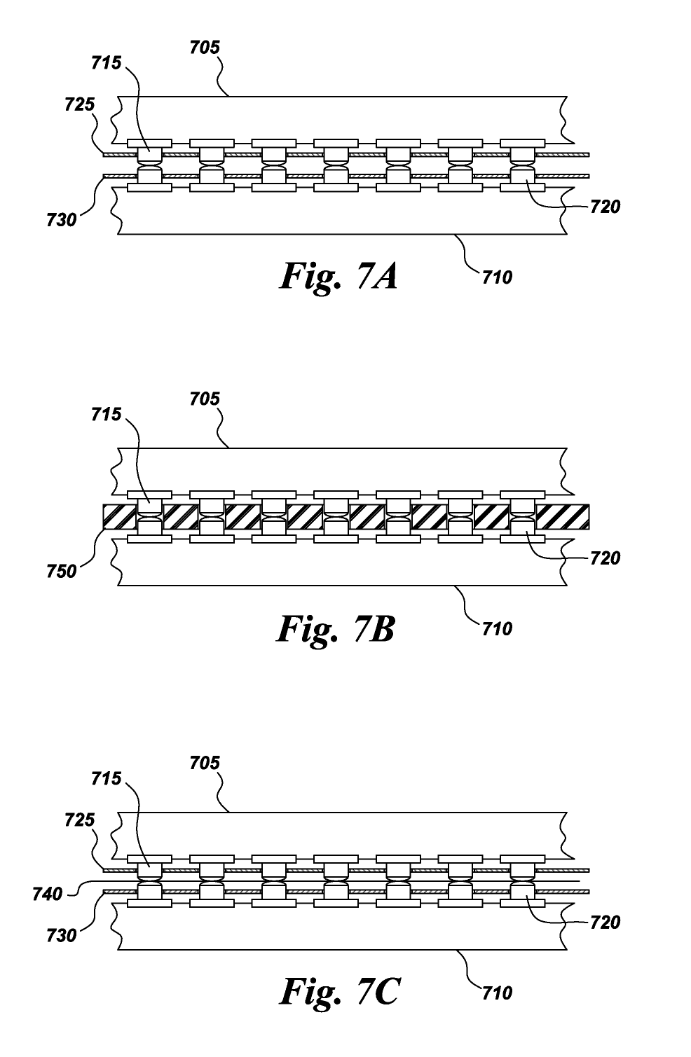

FIG. 7a illustrates a further application of the alignment template for electrically coupling integrated circuits. In one example, each of the integrated circuits 705, 710 have corresponding templates 725, 730 such that the respective protrusions 715, 720 extend therefrom. The two integrated circuits are sandwiched together such that the protrusions form an electrical connection to each other and the integrated circuits are communicatively/electrically coupled. The use of a non-conductive adhesive or epoxy and compressive displacement can be employed as already described. In a further embodiment, only a single template is used for coupling the stacked integrated circuits 705, 710.

In the example of FIG. 7b, a single thicker template 750 is used to align the two stacked integrated circuits 705, 710 such that the protrusions 715 from the first integrated circuit 705 extend into a first side of the template 750. On the opposing side of the template 750, the protrusions 720 from the second integrated circuit extend into the opposing side of the template such that the protrusions 715, 720 are electrically coupled within the template 750.

A further embodiment shown in FIG. 7c includes an electrical interconnect 740. In one example, the interconnect 740 would be positioned at the interface or junction of the protrusions 715, 720 and provide conductive pads or traces to enable electrical connections between the integrated circuits 705, 710 and also allow at least some of the signals to be routed through the electrical interconnect 740 for input/output connectivity. The use of the electrical interconnect 740 allow for further aspects such as bus interface among the protrusions 715, 720 for the respective integrated circuits 705, 710. While shown with templates 725, 730 on each of the integrated circuits 705, 710, a further example only uses one template.

FIGS. 7a, 7b and 7c provide for electrically connecting multiple protrusions on stacked integrated circuits 705, 710. Such connectivity can expand the functionality and capabilities of the integrated circuits and allow for additional features. External input/output or other signal connections can be achieved on edge connectors or through vias that extend to the backside of the integrated circuit. A further feature is the ability to use lower temperature adhesives and bond die at lower temperatures for temperature sensitive die.

As noted herein, it is possible to align a single integrated circuit to provide connection to an interconnect mating surface through the use of alignment tooling that allows x, y, and rotational movement of the integrated circuit. However, the template detailed herein facilitates such alignment and allows for less qualified users to make the alignment. For multiple integrated circuit, the tooling to provide x, y, and rotational movement on each integrated circuit is complex and expensive. The disclosed method and system provides an accurate means for accomplishing alignment that is inexpensive and easier to accomplish than convention techniques. In one example, the protrusions on the integrated circuit surface need to extend above the surface of the alignment template and provide sufficient resistance to the integrated circuit movement during subsequent attachment to the mating surface.

One aspect of the system is the ability to manufacture devices for multiple chip applications where alignment is an issue. This system and method is relatively inexpensive to adjust to any application and improve final manufacturing yield while reducing manufacturing costs.

In one exemplary embodiment, the present technique is utilized with one or more ASICs with a large number of pillars or bumps. In this example, the protrusions are gold pillars that are about 25 microns tall and about 65 microns in diameter. Due to flatness issues with the ASIC copper pads and the flex pads, the present system provided a more robust system for connection to the flex circuit. One project included four ASICs placed in a row with tights spacing requirements. A laser drilled kapton template approximately 12.5 microns thick, which is a standard size, was used and represented about one half the height of the protrusions. An epoxy was disposed between the template and the substrate to hold the template in position. The pitch of these ASICs was about 110 micron.

While only certain features of the present invention have been illustrated and described herein, many modifications and changes will occur to those skilled in the art. It is, therefore, to be understood that the appended claims are intended to cover all such modifications and changes as fall within the true spirit of the invention.

1. An alignment system for electronic devices, comprising:
at least one integrated circuit comprising a plurality of protrusions arranged in a protrusion pattern;
a template with a plurality of holes disposed on the integrated circuit, wherein at least some of the holes are arranged in the protrusion pattern and said holes are disposed onto the protrusions such that a portion of the protrusions extends from the template; and
an interconnect disposed on the template, said interconnect having a plurality of electric contacts, wherein at least some of the electrical contacts are arranged in the protrusion pattern, and wherein at least some of the electrical contacts are electrically coupled to at least some of the protrusions.

2. The system of claim 1, wherein the template has a window such that at least some of the protrusions are electrically coupled to the electrical contacts of the interconnect without going through the holes.

3. The system of claim 1, further comprising a stacked integrated circuit disposed onto said interconnect with a set of protrusions from the stacked integrated circuit being electrically coupled to at least some of the protrusions of the at least one integrated circuit.

4. The system of claim 3, further comprising an additional template disposed on the stacked integrated circuit, wherein the set of protrusions from the stacked integrated circuit extend through a set of holes in the additional template.

5. The system of claim 1, wherein a low temperature non-conductive adhesive is disposed between at least one of the integrated circuit and the template and the template and the interconnect.

6. The system of claim 1, wherein the template comprises polymers glasses, ceramics, composites, or combinations thereof.

7. The system of claim 1, wherein the template comprises kapton or polyethylene terephthalate (PET).

8. The system of claim 1, wherein the integrated circuit comprises at least one application specific integrated circuit, field programmable gate array, and system on a chip.

9. The system of claim 1, wherein the at least one integrated circuit comprises two or more integrated circuits.

10. The system of claim 9, wherein at least one of the integrated circuits has a different size, shape, or protrusion arrangement.

11. The system of claim 1, wherein the template is affixed to a frame.

12. The system of claim 1, wherein the template has a thickness less than a thickness of the protrusion.

13. A method for making electrical semiconductor interconnections, comprising:
providing one or more integrated circuits having a plurality of protrusions arranged in a protrusion pattern;
disposing a template onto said integrated circuits, said template having a plurality of holes arranged in a hole pattern, wherein the hole pattern at least partially matches the protrusion pattern and at least a portion of the protrusions extend from said template; and
disposing an electrical interconnect onto said template, said electrical interconnect having a plurality of electrical contacts arranged in said protrusion pattern, wherein the electrical contacts are electrically coupled to said protrusions.

14. The method of claim 13, further comprising disposing a nonconductive adhesive and applying pressure until cured.

15. The method of claim 13, wherein the holes are produced by perforating or laser drilling.

16. The method of claim 13, further comprising disposing a low temperature non-conductive adhesive between the integrated circuit and the template, the template and the electrial interconnect, or both.

17. The method of claim 13, further comprising aligning at least one of the integrated circuits and the electrical interconnect with an alignment tool.

18. The method of claim 13, further comprising positioning the integrated circuits onto a backing material.

19. A device having aligned integrated circuits, comprising:
a plurality of protrusions on each of the integrated circuits, each of said integrated circuits having a protrusion pattern;
a template with a plurality of holes, wherein the holes are arranged for each said protrusion pattern, said template disposed onto the integrated circuits such that a portion of the protrusions extends from the holes of the template; and
an interconnect disposed over the template, said interconnect having a plurality of electric contacts, wherein the electric contacts are arranged according to the protrusion pattern of the integrated circuits, and wherein the electric contacts are electrically coupled to the protrusions.

20. The device of claim 19, wherein the aligned integrated circuits are aligned based on the protrusion pattern.
